(19) United States
(12) Patent Application Publication
(10) Pub. No.: US 2026/0165114 A1
(43) Pub. Date: Jun. 11, 2026

(54) INTERCONNECT STRUCTURE WITH AIRGAP AND ETCH STOP LAYER

(71) Applicant: International Business Machines Corporation, Armonk, NY (US)

(72) Inventors: Chanro Park, Clifton Park, NY (US); Nicholas Anthony Lanzillo, Wynantskill, NY (US); Koichi Motoyama, Clifton Park, NY (US); Yann Mignot, Slingerlands, NY (US)

(21) Appl. No.: 18/969,411

(22) Filed: Dec. 5, 2024

(51) Int. Cl. H01L 21/768; H01L 23/522

(52) U.S. Cl. CPC H10W 20/46; H10W 20/056; H10W 20/072; H10W 20/075; H10W 20/076; H10W 20/084; H10W 20/42

(57) ABSTRACT

A semiconductor interconnect structure and formation thereof. The semiconductor interconnect structure includes a first interlayer dielectric (ILD) layer and a second ILD layer formed above the first ILD layer. The semiconductor interconnect structure further includes two adjacent metal lines formed within the second ILD layer and an air gap formed within a portion of the second ILD layer located between the two adjacent metal lines. The first ILD layer directly contacts the second ILD layer in a first region located below the air gap, and the first ILD layer and the second ILD layer are separated by an etch stop layer in a second region located outside of the first region.

### BACKGROUND

The present disclosure generally relates to fabrication methods and structures for semiconductor devices, and more specifically, to fabricating a semiconductor interconnect structure using a via-first dual damascene process.

For an integrated circuit (IC) device to be functional, multi-level or multi-layered interconnection schemes such as, for example, metal wiring formed by additive manufacturing processes (e.g., single damascene processes or dual damascene processes), subtractive manufacturing processes (e.g., subtractive etching processes), and combinations thereof, are fabricated in the back-end-of-the-line (BEOL) of the device to connect the circuit elements distributed in the front-end-of-the-line (FEOL) of the device. Connections between the metal lines of the different interconnect levels, called vias, allow signals and power to be transmitted between one level to the next.

### SUMMARY

According to one embodiment of the present invention, a semiconductor interconnect structure is provided. The semiconductor interconnect structure includes a first interlayer dielectric (ILD) layer and a second ILD layer formed above the first ILD layer. The semiconductor interconnect structure further includes two adjacent metal lines formed within the second ILD layer and an air gap formed within a portion of the second ILD layer located between the two adjacent metal lines. The first ILD layer directly contacts the second ILD layer in a first region located below the air gap, and the first ILD layer and the second ILD layer are separated by an etch stop layer in a second region located outside of the first region.

According to another embodiment of the present invention, a method of forming a semiconductor interconnect structure is provided. The method includes forming a material stack including, from bottom to top, a first interlayer dielectric (ILD) layer, an etch stop layer, and a second ILD layer. The method further includes forming a via in the first ILD layer and two adjacent metal lines in the second ILD layer using a via-first dual damascene process. The method further includes forming openings between the two adjacent metal lines by removing respective portions of the second ILD layer and the etch stop layer located between the two adjacent metal lines. The method further includes filling the openings with a dielectric material in a manner that forms an air gap located between the two adjacent metal lines.

### BRIEF DESCRIPTION OF THE SEVERAL VIEWS OF THE DRAWINGS

The drawings included in the present application are incorporated into, and form part of, the specification. They illustrate embodiments of the present invention and, along with the description, explain the principles of the invention. The drawings are only illustrative of certain embodiments and do not limit the invention.

FIG. 1 illustrates a cross-sectional view of a semiconductor interconnect structure 100 at an intermediate step during a semiconductor manufacturing process, in accordance with at least one embodiment of the present invention.

FIG. 2 illustrates a cross-sectional view of semiconductor interconnect structure 100 of FIG. 1 after performing subsequent processing steps, in accordance with at least one embodiment of the present invention.

FIG. 3 illustrates a cross-sectional view of semiconductor interconnect structure 100 of FIG. 2 after performing subsequent processing steps, in accordance with at least one embodiment of the present invention.

FIG. 4 illustrates a cross-sectional view of semiconductor interconnect structure 100 of FIG. 3 after performing subsequent processing steps, in accordance with at least one embodiment of the present invention.

FIG. 5 illustrates a cross-sectional view of semiconductor interconnect structure 100 of FIG. 4 after performing subsequent processing steps, in accordance with at least one embodiment of the present invention.

FIG. 6 illustrates a cross-sectional view of semiconductor interconnect structure 100 of FIG. 5 after performing subsequent processing steps, in accordance with at least one embodiment of the present invention.

FIG. 7 illustrates a cross-sectional view of semiconductor interconnect structure 100 of FIG. 6 after performing subsequent processing steps, in accordance with at least one embodiment of the present invention.

FIG. 8 illustrates a cross-sectional view of semiconductor interconnect structure 100 of FIG. 7 after performing subsequent processing steps, in accordance with at least one embodiment of the present invention.

### DETAILED DESCRIPTION

The present disclosure generally relates to fabrication methods and structures for semiconductor devices, and more specifically, to fabricating a semiconductor interconnect structure using a via-first dual damascene process.

In conventional interconnect schemes, connections between the metal lines of the different interconnect levels, called vias, allow signals and power to be transmitted between one level to the next. When fabricating integrated circuit wirings within a multi-layered scheme, an insulating or dielectric material (e.g., silicon oxide or a low-κ insulator) will normally be patterned with several thousand openings to create conductive line openings and/or via openings using single or dual damascene processes. The line openings and via openings are typically filled with a conductive metal material (e.g., copper, aluminum, etc.) to electrically interconnect the active and/or passive elements of the integrated circuits.

In tight pitch interconnect schemes, it is crucial that a minimum via-to-line distance be maintained between vias and neighboring metal lines to reduce the risk of electrical shorts. Forming the vias with substantially vertical sidewall profiles is one way of ensuring that this minimum distance is maintained. However, the ability to form vias with substantially vertical sidewall profiles has proven to be difficult, especially when utilizing the via-first dual damascene process. With a via-first dual damascene process, the via portions of the interconnect structure are typically not protected during the trench dielectric etch. As such, the trench dielectric etch can cause chamfering of the top corners of the via, which ultimately results in the via having a rounded or chamfered sidewall profile. As the chamfer angle of the sidewall profile decreases, the distance between the via and the neighboring metal lines also decreases. This ultimately results in a reduction in the via-to-line distance between the via and neighboring metal lines. Generally, a chamfer angle less than 80 degrees is not desirable, as this can lead to shorting issues.

One possible solution to control via chamfering in a via-first dual damascene process is to introduce an advanced etch stop layer (aESL) prior to the deposition of an interlayer dielectric (ILD) layer. The aESL, which is generally formed from a multilayered material stack (e.g., aluminum oxide (AlO)/oxygen doped carbon (ODC)/aluminum oxide (AlO)), only limits via chamfering during the trench dielectric etch to the bottom portion of the via opening formed in the aESL, while the top portion of the via opening formed in the ILD may still be subjected to via chamfering. Thus, the introduction of an aESL below the ILD layer still results in a reduction in the via-to-line distance between the top portion of the via and any neigboring metal lines. Moreover, embodiments of the present invention recognize that this process is both cost and labor intensive, in that multiple deposition and etching steps are required to form and pattern the aESL. For example, an aESL formed from a multilayer material stack of AlO, ODC, and AlO not only requires the deposition of three different materials, but also requires multiple different etching processes (e.g., wet etching for each layer of AlO and dry etching for the layer of ODC).

Embodiments of the present invention provide for a semiconductor interconnect structure, and a method of making the same, which improve upon the foregoing deficiencies of conventional processes for via chamfer control during via-first dual damascene processes. Embodiments of the present invention recognize that the insertion of a single layer of etch stop material between the via portion and the trench portion of the ILD is an effective way to control the via profile without the added cost and processing steps associated with an aESL positioned below the ILD. The presence of the single layer of etch stop material between the via portion and the trench portion of the ILD protects the dielectric material surrounding the via opening during the trench dielectric etch, thereby significantly reducing and/or eliminating chamfering of the via opening sidewalls during the trench dielectric etch. In doing so, the required minimum via-to-line distance between the via and neighboring metal lines is maintained. This ultimately results in a reduced risk of electric shorts and improved device reliability.

Although the insertion of the etch stop layer between the via portion and the trench portion of the ILD effectively reduces and/or eliminates via chamfering during the trench dielectric etch portion of the via-first dual damascene process, embodiments of the present invention recognize that this realized benefit does not come without a performance penalty, especially in tight pitch interconnect schemes. Namely, an increase in the parasitic capacity between adjacent metal lines will occur due to the higher dielectric constant (κ) of the etch stop material (e.g., ˜10 for AlO) as compared to dielectric material of the ILD (e.g., ˜4 for SiO₂).

To address this performance penalty caused by the higher dielectric constant (κ) of the etch stop layer, the dielectric material located between adjacent metal lines is initially removed in order to remove the respective portions of the etch stop layer located thereunder. The areas between the adjacent metal lines are subsequently backfilled with a dielectric material in a manner that forms airgaps between the adjacent metal lines. This results in a significant reduction in the intra-level parasitic capacitance between adjacent metal lines since air has a dielectric constant (κ) of ˜1.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this invention may be embodied in many different forms and should not be construed as limited to the exemplary embodiments set forth herein. Rather, these exemplary embodiments are provided so that this invention will be thorough and complete and will fully convey the scope of this invention to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” may mean that a first element can be etched, and the second element can act as an etch stop.

As used herein, terms such as “depositing,” “forming,” and the like may refer to the disposition of layers, or portions of materials, in accordance with a given embodiment. Such processes may or may not be different than those used in the standard practice of the art of semiconductor device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may also refer to processes that alter the structure and/or composition of one or more layers of material or portions of materials in accordance with a given embodiment. For example, such formation processes may include, but are not limited to, micromachining, microetching, wet and/or dry etching processes, plasma etching processes, or any of the known etching processes in which material is removed to form a particular structure.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

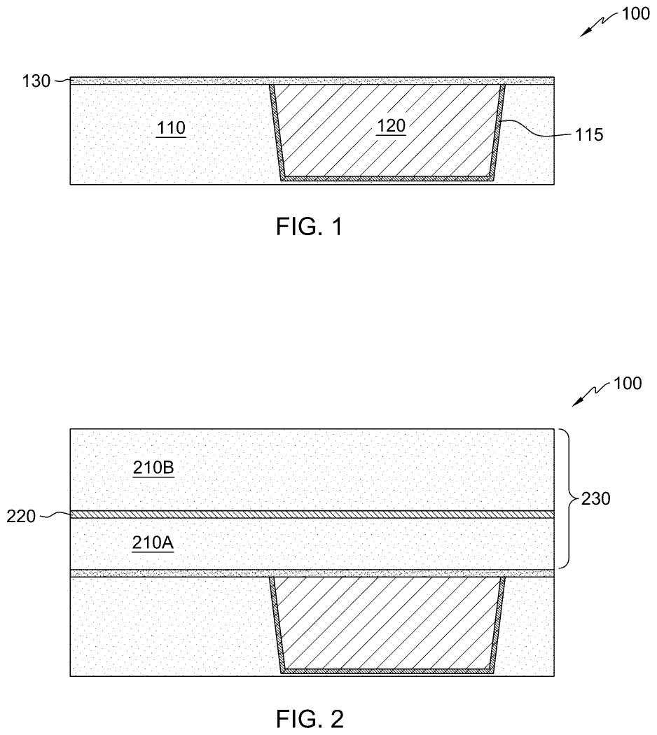

The present invention will now be described in detail with reference to the Figures, in which like numbers represent the same or similar elements. FIGS. 1-8 include various cross-sectional views depicting illustrative steps of methods for manufacturing semiconductor interconnect structures using a via-first dual damascene process, and the resulting semiconductor interconnect structures according to select embodiments of the present invention. One having ordinary skill in the art will appreciate that there are many options available for the formation of the structures described herein and that the following discussion does not limit embodiments to only the techniques described herein.

FIG. 1 depicts a cross-sectional view of a semiconductor interconnect structure 100 at an intermediate step during a semiconductor manufacturing process, in accordance with at least one embodiment of the present invention. In assembly of semiconductor interconnect structure 100 of FIG. 1, a metal line 120 is formed within an interlayer dielectric (ILD) layer 110, and a dielectric capping layer 130 is formed on top thereof. Collectively, the metal line 120 and the ILD layer 110 are part of an interconnect level (e.g., M1 metal level). It should be noted that one or more additional metal lines (not depicted) may be formed within the ILD layer 110, but that these other metal lines are not shown for clarity. Similarly, one or more additional back-end-of-the-line (BEOL) interconnect levels and/or middle-of-the-line (MOL) interconnect levels may be located beneath this interconnect level (also not shown for clarity).

The ILD layer 110 may be formed by depositing a dielectric material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The ILD layer 110 may be composed of an inorganic dielectric material or an organic dielectric material. Examples of suitable dielectric materials that may be employed as the ILD layer 110 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl. In some embodiments, the ILD layer 110 may have a dielectric constant (all dielectric constants mentioned herein are measured relative to a vacuum, unless otherwise stated) that is about 4.0 or less. In an embodiment, the ILD layer 110 may have a dielectric constant of 2.8 or less. Dielectric materials having a dielectric constant of 2.8 or less generally have a lower parasitic cross talk as compared to dielectric materials whose dielectric constant is greater than 4.0. In some embodiments, the ILD layer 110 may be porous. In other embodiments, the ILD layer 110 may be non-porous.

The metal line 120 may be formed within the ILD layer 110 using one or more conventional BEOL semiconductor manufacturing processes (e.g., a damascene process or a dual damascene process) as known by one of ordinary skill in the art, and as such, a more detailed description of such processes is not presented herein. The metal line 120 may be composed of a conductive material including, but not limited to, copper (Cu), aluminum (Al), ruthenium (Ru), rhodium (Rh), iridium (Ir), tantalum (Ta), tantalum nitride (TaN) titanium (Ti), titanium nitride (TiN), tungsten (W), molybdenum (Mo), nickel (Ni), or any combination thereof.

In some embodiments, and as depicted in FIG. 1, a diffusion barrier liner 115 surrounds the bottom and sidewall surfaces of the metal line 120 formed within the ILD layer 110. The diffusion barrier liner 115 is composed of a diffusion barrier material (i.e., a material that serves as a barrier to prevent the conductive material used to form the metal line 120 from diffusing into the ILD layer 110). The diffusion barrier liner 115 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN), or combinations of barrier materials such as RuTaN, Ta/TaN, CoWP, NiMoP, or NiMoB which are suitable for the given application.

Following the formation of the metal line 120 within the ILD layer 110, a dielectric capping layer 130 is formed by depositing a dielectric capping material onto the ILD layer 110, diffusion barrier liner 115, and metal line 120 using known deposition techniques, including, but not limited to, chemical vapor deposition (CVD), plasma enhanced chemical vapor deposition (PECVD), atomic layer deposition (ALD), physical vapor deposition (PVD), sputtering, chemical solution deposition, or plating. Suitable dielectric capping materials for the dielectric capping layer 130 may include, but are not limited to, silicon carbide (SiC), silicon nitride (SiN), silicon carbide nitride (SiCN), a nitrogen and hydrogen-doped silicon carbide (SiC(N, H)), or any combination thereof.

FIG. 2 illustrates a cross-sectional view of semiconductor interconnect structure 100 of FIG. 1 after performing subsequent processing steps, in accordance with at least one embodiment of the present invention. In assembly of semiconductor interconnect structure 100 of FIG. 2, a material stack 230 is formed that includes, from bottom to top, a first interlayer dielectric (ILD) layer 210A (also referred to herein as the via portion of an ILD), an etch stop layer (ESL) 220, and a second ILD layer 210B (also referred to herein as the trench portion of an ILD). In other words, the etch stop layer 220 is located between or otherwise physically separates the first ILD layer 210A from the second ILD layer 210B.

The material stack 230 may be formed by a multilayer deposition process, including depositing alternating layers of dielectric and etch stop materials using known deposition techniques, including, but not limited to, chemical vapor deposition (CVD), plasma enhanced chemical vapor deposition (PECVD), atomic layer deposition (ALD), physical vapor deposition (PVD), sputtering, chemical solution deposition, or plating. The first and second ILD layers 210A, 210B may be composed of any of the dielectric materials previously described with respect to the ILD layer 110 of FIG. 1. Suitable etch stop materials for the etch stop layer 220 may include, but are not limited to, aluminum oxide (AlO), aluminum nitride (AlN), hafnium oxide (HfO), tantalum oxide (TaO), zirconium oxide (ZrO), an oxygen-doped silicon carbide (ODC), or any combination thereof.

In some embodiments, and as depicted in FIG. 2, the etch stop layer 220 is formed from a single layer of etch stop material. However, in other embodiments, the etch stop layer 220 may be formed from multiple layers of similar or different etch stop materials. The thickness of the etch stop layer 220 may vary depending on the deposition process used, the number of layers of material deposited, as well as the material employed. In some embodiments, the etch stop layer 220 may have a thickness that ranges between 2 nanometers and 10 nanometers. However, other thicknesses may be contemplated.

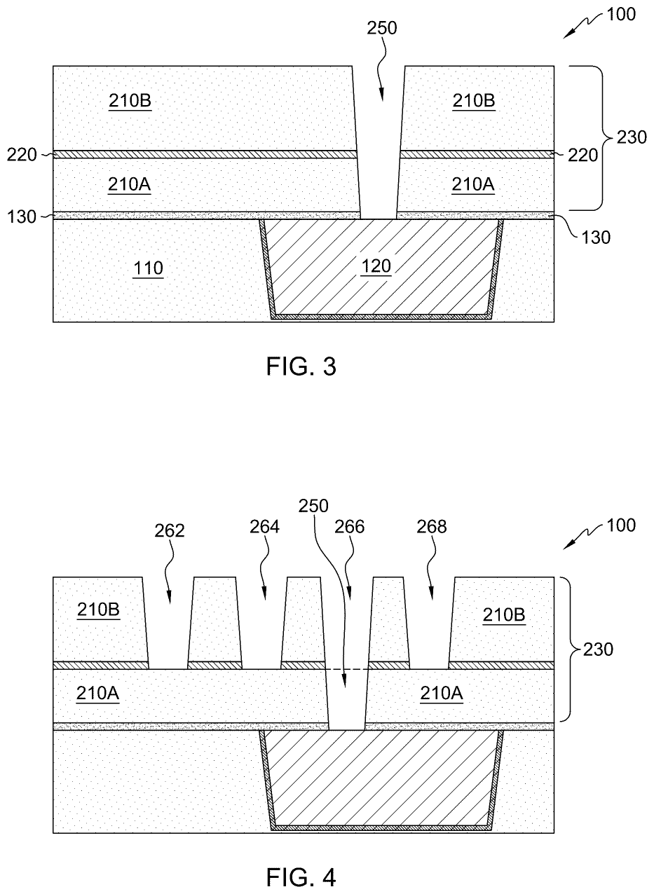

FIG. 3 illustrates a cross-sectional view of semiconductor interconnect structure 100 of FIG. 2 after performing subsequent processing steps, in accordance with at least one embodiment of the present invention. In assembly of semiconductor interconnect structure of FIG. 3, the dielectric capping layer 130 and the material stack 230 are patterned to form a via opening 250 located above the metal line 120 embedded within the ILD layer 110. This step may generally be referred to as the via portion of a via-first dual damascene process.

The dielectric capping layer 130 and the material stack 230 may be patterned using one or more conventional patterning processes (e.g., lithography and etching) to form the via opening 250. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the top surface of the material stack 230, and the hard mask material is patterned to form a patterned hard mask (not depicted). Then, using the patterned hard mask, the material stack 230 and the dielectric capping layer 130 are etched (using, for example, reactive ion etching (RIE), ion beam etching (IBE), chemical wet etching, or any combination thereof) to form the via opening 250. The resulting structure may be subjected to a wet clean.

The etching of the material stack 230 and the dielectric capping layer 130 can be controlled by a timed etching process as known by one of ordinary skill in the art, such that the etching process is terminated upon reaching the top surface of the metal line 120. As depicted by FIG. 3, the via opening 250 extends completely through the material stack 230 (i.e., completely through the second ILD layer 210B, the etch stop layer 220, and the first ILD layer 210A) and the dielectric capping layer 130, such that the via opening 250 exposes the top surface the metal line 120. One or more additional via openings (not depicted) may be contemplated but are not shown for clarity.

FIG. 4 illustrates a cross-sectional view of semiconductor interconnect structure 100 of FIG. 3 after performing subsequent processing steps, in accordance with at least one embodiment of the present invention. In assembly of semiconductor interconnect structure of FIG. 4, the material stack 230 is further patterned to form trench openings 262-268. This step may generally be referred to as the trench portion of the via-first dual damascene process.

The material stack 230 may be further patterned using one or more conventional patterning processes (e.g., lithography and etching) to form the trench openings 262-268. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering), and the hard mask material is patterned to form a patterned hard mask (not depicted). Then, using the patterned hard mask, the material stack 230 is etched using, for example, reactive ion etching (RIE), ion beam etching (IBE), chemical wet etching, or any combination thereof) to form the trench openings 262-268. The resulting structure may be subjected to a wet clean.

The depth of the trench openings 262-268 can be controlled by a timed etching process as known by one of ordinary skill in the art, such that the etching process is terminated upon reaching the top surface of the first ILD layer 210A (i.e., the top surface of the via portion of the ILD). As depicted by FIG. 4, trench openings 262-268 extend completely through both the second ILD layer 210B and the etch stop layer 220, such that the trench openings 262-268 expose the top surface of the first ILD layer 210A (i.e., the top surface of the via portion of the ILD).

It should be appreciated that the insertion of the etch stop layer 220 between the first ILD layer 210A (i.e., the via portion of the ILD) and the second ILD layer 210B (i.e., the trench portion of the ILD) reduces and/or eliminates any chamfering of the top corners of the via opening 250 during the trench dielectric etch portion of the dual damascene process. This is evinced by the fact that the sidewall profile of the via opening 250 remains substantially unaltered after the trench dielectric etch. This is particularly advantageous in that the distance between the sidewalls of the via opening 250 and the neighboring trench openings (i.e., trench openings 264, 268) is maintained after the trench dielectric etch.

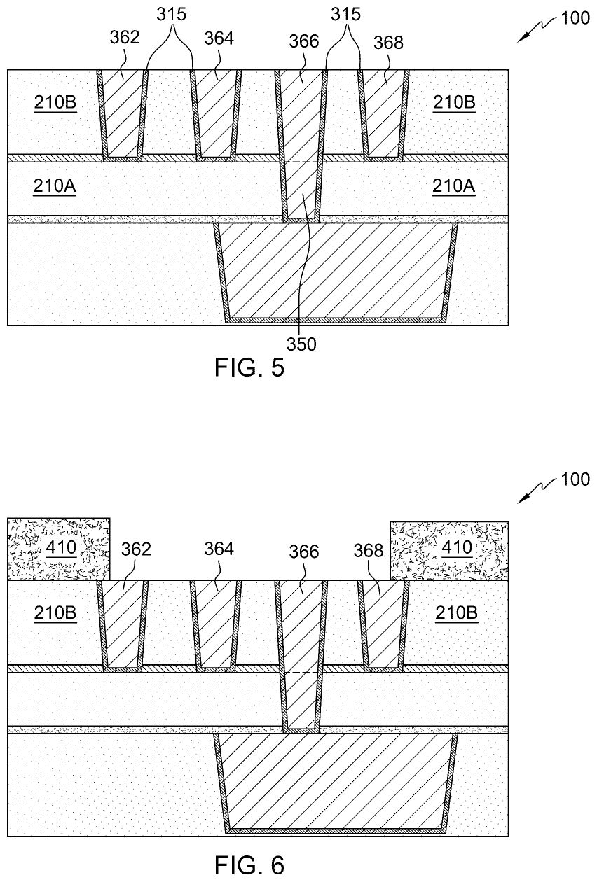

FIG. 5 illustrates a cross-sectional view of semiconductor interconnect structure 100 of FIG. 4 after performing subsequent processing steps, in accordance with at least one embodiment of the present invention. In assembly of semiconductor interconnect structure 100 of FIG. 5, a single deposition step is performed to fill the via opening 250 (depicted in FIG. 4) and trench openings 262-268 (depicted in FIG. 4) with a conductive material, followed by a planarization process. The filling of the via opening 250 with the conductive material results in the formation of a via 350, while the filling of the trench openings 262-268 with the conductive material results in the formation of metal lines 362-368. As depicted in FIG. 5, the via 350 is in electrical contact with the metal line 366. It should be noted that one or more additional vias (not depicted) may be formed within the first ILD layer 210A, but that these other vias are not shown for clarity.

The conductive material may be deposited within the via opening 250 (depicted in FIG. 4) and the trench openings 262-268 (depicted in FIG. 4) using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The conductive material used to form the via 350 and metal lines 362-368 may be a metal including, but not limited to, copper (Cu), aluminum (Al), ruthenium (Ru), rhodium (Rh), iridium (Ir), tungsten (W), molybdenum (Mo), nickel (Ni), or any combination thereof.

In some embodiments, and as depicted in FIG. 5, a diffusion barrier liner 315 is formed along the bottom and sidewall surfaces of the via opening 250 (depicted in FIG. 4) and trench openings 262-268 (depicted in FIG. 4) prior to depositing the conductive material. The diffusion barrier liner 315 is composed of a diffusion barrier material (i.e., a material that serves as a barrier to prevent the conductive material used to form the via 350 and metal lines 362-368 from diffusing into the first and second ILD layers 210A, 210B. The diffusion barrier liner 315 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN), or combinations of barrier materials such as RuTaN, Ta/TaN, CoWP, NiMoP, or NiMoB which are suitable for the given application.

Following the deposition of the conductive material, a planarization process such as, for example, chemical mechanical planarization or polishing (CMP), and/or grinding may be performed to remove portions of the conductive material located above the top surface of the second ILD layer 210B. The planarization stops at the top surface of the second ILD layer 210B, such that a top surface of the metal lines 362-368 is substantially coplanar with the top surface of the second ILD layer 210B.

FIG. 6 illustrates a cross-sectional view of semiconductor interconnect structure 100 of FIG. 5 after performing subsequent processing steps, in accordance with at least one embodiment of the present invention. In assembly of semiconductor interconnect structure 100 of FIG. 6, a patterned mask 410 is formed. The patterned mask 410, which acts as an etch mask, is formed such that the respective portions of the dielectric material of the second ILD layer 210B located between the metal lines 362-368 are left exposed, while the remaining portions of the dielectric material are concealed by the patterned mask 410.

By way of example, the patterned mask 410 may be formed as follows. An inorganic hard mask material (e.g., silicon nitride, titanium nitride, tantalum nitride, or any suitable inorganic metal-containing material) or an organic soft mask material (e.g., carbon, hydrogen, oxygen, and optionally nitrogen, fluorine, and silicon) is deposited, followed by the deposition of photoresist material (not depicted) on top thereof using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. A photomask (not depicted) patterned with shapes defining the patterned structure to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the mask material. Dry etch techniques (for example, an anisotropic etch process, such as reactive ion etch) may be employed to selectively remove portions of the mask material to form the patterned mask 410. After formation of the patterned mask 410, the photoresist material may be stripped from the patterned mask 410 by ashing or other suitable processes. The resulting structure may be subjected to a wet clean.

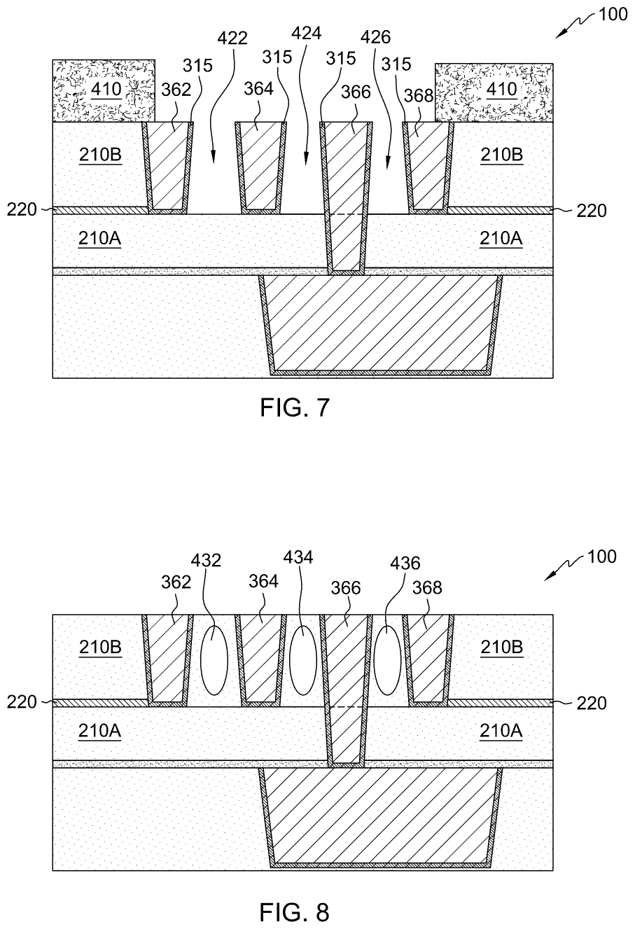

FIG. 7 illustrates a cross-sectional view of semiconductor interconnect structure 100 of FIG. 6 after performing subsequent processing steps, in accordance with at least one embodiment of the present invention. In assembly of semiconductor interconnect structure 100 of FIG. 7, the respective portions of ILD layer 210B and etch stop layer 220 located between the metal lines 362-368 are removed using one or more conventional material removal processes as known by one of ordinary skill in the art.

As previously described above, although the insertion of the etch stop layer 220 between the first ILD layer 210A (i.e., the via portion of the ILD) and the second ILD layer 210B (i.e., the trench portion of the ILD) effectively reduces and/or eliminates via chamfering during the trench dielectric etch of the via-first dual damascene process, an increase in the parasitic capacity between the metal lines 362-368 will occur due to the higher dielectric constant (κ) of the etch stop material (e.g., ˜10 for AlO) as compared to the dielectric constant (κ) of the dielectric material of the first and second ILD layers 210A, 210B (e.g., ˜4 for SiO₂).

To address this performance penalty caused by the higher dielectric constant of the etch stop layer 220, the dielectric material located between metal lines 362-368 is initially removed in order to remove the respective portions of the etch stop layer 220 located thereunder. For example, using the patterned mask 410, which acts as an etch mask, the physically exposed portions of the second ILD layer 210B, and the respective portions of the etch stop layer 220 located underneath, are removed using one or more etching processes (e.g., reactive ion etching (RIE), ion beam etching (IBE), chemical wet etching, or any combination thereof). The etching can be controlled by a timed etching process as known by one of ordinary skill in the art, such that the etching process is terminated upon reaching the top surface of the first ILD layer 210A (i.e., the top surface of the via portion of the ILD). The resulting structure may be subjected to a wet clean. As depicted by FIG. 7, the removal of the dielectric material of the second ILD layer 210B and etch stop layer 220 located between the metal lines 362-368 further results in the formation of openings 422-426 located between the metal lines 362-368 that expose the top surface of the first ILD layer 210A.

In some embodiments, a multi-step etching process may be performed to remove the second ILD layer 210B and the etch stop layer 220, respectively. For example, a first wet etching process that incorporates a chemical etchant that is selective to the material of the second ILD layer 210B may be used to remove the portions of the ILD layer 210B located between the metal lines 362-368, while a second wet etching process that incorporates a different chemical etchant that is selective to the material of the etch stop layer 220 may be used to remove the portions of the etch stop layer 220 located between the metal lines metal lines 362-368. It should be appreciated that although embodiments of the present invention may utilize any generally known types of material removal processes to remove the second ILD layer 210B and etch stop layer 220, it may be preferable to use wet etching processes to limit any damage to the diffusion barrier liner 315 during the material removal process.

FIG. 8 illustrates a cross-sectional view of semiconductor interconnect structure 100 of FIG. 7 after performing subsequent processing steps, in accordance with at least one embodiment of the present invention. In assembly of semiconductor interconnect 100 of FIG. 8, the patterned mask 410 (depicted in FIG. 7) is removed, and the openings 422-426 (depicted in FIG. 7) are backfilled with a dielectric material.

After removal of the patterned mask 410 (depicted in FIG. 7) using one or more processes as known by one of ordinary skill in the art, a dielectric material is deposited within the openings 422-426 (depicted in FIG. 7) in a manner that results in the formation of air gaps 432-436 within the dielectric material located between the metal lines 432-436. The dielectric material may be deposited using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition, and may include any of the dielectric materials previously described with respect to the ILD layer 110 of FIG. 1. Following the deposition of the dielectric material, a planarization process such as, for example, chemical mechanical planarization or polishing (CMP), and/or grinding, may subsequently be performed to create a substantially planar top surface.

As depicted by FIG. 8, the deposition of the dielectric material within the openings 422-426 further results in the formation of air gaps 432-436 within the dielectric material located between the metal lines 362-368. Due to the overhang phenomenon that occurs when an insulating film is simultaneously deposited on the entrance, sidewalls, or the bottom surface of an opening having a high aspect ratio, the top of the opening can be blocked before the opening is completely filled, generating air gaps inside the opening. Typically, air gaps will naturally occur when the aspect ratio of the area being filled is greater than 1 (and more frequently as the aspect ratio of the opening increases). In the instant case, since the openings 422-426 (depicted in FIG. 7) have a high aspect ratio (i.e., the vertical dimensions of the openings are greater than the lateral dimensions of the openings), the air gaps 432-436 will naturally form between the metal lines 362-368 during the filling of the openings 422-426 with the dielectric material.

As further depicted by FIG. 8, the first ILD layer 220A (i.e., the via portion of the ILD) is in direct contact with the second ILD layer 210B (i.e., the trench portion of the ILD) in a first set of regions below the air gaps 432-436. However, the first ILD layer 210A and the second ILD layer 210B remain separated by the etch stop layer 220 in a second set of regions located outside of the first set of regions. In other words, the ILD layers 210A, 210B remain physically separated by the etch stop layer 220 in those regions below corresponding areas of the second ILD layer 210B in which air gaps are not present.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor interconnect structure, comprising:
a first interlayer dielectric (ILD) layer;
a second ILD layer formed above the first ILD layer;
two adjacent metal lines formed within the second ILD layer; and
an air gap formed within a portion of the second ILD layer located between the two adjacent metal lines,
wherein the first ILD layer directly contacts the second ILD layer in a first region located below the air gap, and
wherein the first ILD layer and the second ILD layer are separated by an etch stop layer in a second region located outside of the first region.

2. The semiconductor interconnect structure of claim 1, wherein the etch stop layer is formed from a single layer of etch stop material.

3. The semiconductor interconnect structure of claim 2, wherein the etch stop material is selected from the group consisting of aluminum oxide (AlO), aluminum nitride (AlN), hafnium oxide (HfO), tantalum oxide (TaO), zirconium oxide (ZrO), and oxygen-doped silicon carbide (ODC).

4. The semiconductor interconnect structure of claim 1, wherein a thickness of the etch stop layer ranges from 2 to 10 nanometers.

5. The semiconductor interconnect structure of claim 1, wherein a first dielectric constant of the etch stop layer is greater than a second dielectric constant of the first and second ILD layers.

6. The semiconductor interconnect structure of claim 1, wherein bottom surfaces of the two adjacent metal lines are substantially coplanar with a bottom surface of the etch stop layer.

7. The semiconductor interconnect structure of claim 1, further comprising a via formed within the first ILD layer, the via in electrical contact with one of the two adjacent metal lines formed within the second ILD layer.

8. The semiconductor interconnect structure of claim 7, wherein a top surface of the via is substantially coplanar with a bottom surface of the etch stop layer.

9. The semiconductor interconnect structure of claim 7, wherein the via and the two adjacent metal lines are formed using a via-first dual damascene process.

10. The semiconductor interconnect structure of claim 7, wherein the via and the two adjacent metal lines are formed from compositionally similar conductive materials.

11. A method of forming a semiconductor interconnect structure, comprising:
forming a material stack including, from bottom to top, a first interlayer dielectric (ILD) layer, an etch stop layer, and a second ILD layer;
forming a via in the first ILD layer and two adjacent metal lines in the second ILD layer using a via-first dual damascene process;
forming openings between the two adjacent metal lines by removing respective portions of the second ILD layer and the etch stop layer located between the two adjacent metal lines; and
filling the openings with a dielectric material in a manner that forms an air gap located between the two adjacent metal lines.

12. The method of claim 11, wherein forming the via and the two adjacent metal lines includes:
forming a via opening that extends completely through the second ILD layer and the etch stop layer, and at least partially through the first ILD layer;
forming two adjacent trench openings that extend completely through the second ILD layer and the etch stop layer; and
simultaneously filling the via opening and the two adjacent trench openings with a conductive material.

13. The method of claim 11, further comprising conformally depositing a dielectric barrier material onto the bottom and sidewall surfaces of the via opening and the two adjacent trench openings prior to simultaneously filling the via opening and the two adjacent trench openings with the conductive material.

14. The method of claim 11, wherein one of the two adjacent metal lines are formed above and in electrical contact with the via.

15. The method of claim 11, wherein the first ILD layer directly contacts the second ILD layer in a first region located below the air gap.

16. The method of claim 13, wherein the first ILD layer and the second ILD layer are separated by the etch stop layer in a second region located outside of the first region.

17. The method of claim 11, wherein the etch stop layer is formed from a single layer of etch stop material.

18. The method of claim 17, wherein the etch stop material is selected from the group consisting of aluminum oxide (AlO), aluminum nitride (AlN), hafnium oxide (HfO), tantalum oxide (TaO), zirconium oxide (ZrO), and oxygen-doped silicon carbide (ODC).

19. The semiconductor interconnect structure of claim 11, wherein a thickness of the etch stop layer ranges from 2 to 10 nanometers.

20. The method of claim 11, wherein a first dielectric constant of the etch stop layer is greater than a second dielectric constant of the first and second ILD layers.
